(19) United States
(12) Patent Application Publication
(10) Pub. No.: US 2020/0219947 A1
(43) Pub. Date: Jul. 9, 2020

(54) DISPLAY PANEL, MANUFACTURING METHOD THEREOF AND DISPLAY DEVICE

(71) Applicant: BOE TECHNOLOGY GROUP CO., LTD., Beijing (CN)

(72) Inventors: Shengji YANG, Beijing (CN); Xiaochuan CHEN, Beijing (CN); Can ZHANG, Beijing (CN)

(73) Assignee: BOE TECHNOLOGY GROUP CO., LTD., Beijing (CN)

(21) Appl. No.: 15/751,739

(22) PCT Filed: Jun. 21, 2017
(86) PCT No.: PCT/CN2017/089341

§ 371 Date: Feb. 9, 2018

(30) Foreign Application Priority Data
Nov. 11, 2016 (CN) 201610995314.9

(51) Int. Cl. H01L 27/32; H01L 27/146; H01L 51/56

(52) U.S. Cl. CPC H01L 27/3234; H01L 51/56; H01L 27/326; H01L 27/14605

(57) ABSTRACT

Embodiments of the present disclosure provide a display panel, a manufacturing method thereof and a display device. The display panel includes: a semiconductor base substrate, a display array, an imaging array and an image recognition unit. The display array is formed on the semiconductor base substrate and includes a plurality of display pixels arranged in an array, each display pixel includes at least one display subpixel, and each display subpixel includes a light-emitting element. The imaging array is formed on the semiconductor base substrate and includes a plurality of imaging pixels, each imaging pixel includes at least one imaging subpixel, and a plurality of display subpixels are mixed with a plurality of imaging subpixels. The image recognition unit is configured to recognize an image acquired by the imaging array.

### TECHNICAL FIELD

Embodiments of the present disclosure relate to a display panel, a display device and a method for manufacturing the display panel.

### BACKGROUND

Microdisplay based on light-emitting diode (LED) is one of the hot spots in the research fields of virtual reality (VR) and augmented reality (AR). Compared with liquid crystal display (LCD), the LED-based microdisplay has advantages such as small volume, low power consumption, low production cost, self-luminesence, wide viewing angle and rapid response speed and hence begin to gradually replace the traditional LCD in the display fields such as smart glasses, head-mounted displays and night vision meters.

### SUMMARY

An embodiment of the present disclosure provides a display panel, a display device and a method for manufacturing the display panel. By integrating human-body biological recognition function into the display panel, the safety of the display panel can be improved and meanwhile the volume and the weight of the display panel and the display device can be reduced.

An embodiment of the present disclosure provides a display panel, the display panel comprises: a semiconductor base substrate; a display array, formed on the semiconductor base substrate and including a plurality of display pixels arranged in an array, in which each of the plurality of display pixels includes at least one display subpixel, and each display subpixel includes a light-emitting element; an imaging array, formed on the semiconductor base substrate and including a plurality of imaging pixels, in which each of the plurality of imaging pixel includes at least one imaging subpixel, and a plurality of display subpixels and a plurality of imaging subpixels are arranged in a mixed arrangement; and an image recognition unit, configured to recognize an image acquired by the imaging array.

For example, in the display panel provided by an example of the present disclosure, each of the plurality of imaging subpixels includes a photoelectric detection unit, and the photoelectric detection unit includes a photoelectric sensor.

For example, in the display panel provided by an example of the present disclosure, each of the plurality of imaging pixels is disposed between two, three or four adjacent display pixels of the plurality of display pixels.

For example, in the display panel provided by an example of the present disclosure, each of the plurality of display pixels includes at least three display subpixels, the light-emitting elements of the at least three display subpixels in the display pixel emit lights with different colors, and each of the plurality of imaging subpixels is disposed between two, three or four adjacent display subpixels of the plurality of display subpixels.

For example, in the display panel provided by an example of the present disclosure, an operating band of the imaging pixel is one or a combination of 400 nm-799 nm, 800 nm-1,200 nm and 1,201 nm-2,500 nm.

For example, in the display panel provided by an example of the present disclosure, material of the semiconductor base substrate include monocrystalline, germanium or gallium arsenide.

For example, the display panel provided by an example of the present disclosure further comprises an infrared light source, wherein the infrared light source is disposed on the semiconductor base substrate and configured to emit infrared light to a user.

For example, in the display panel provided by an example of the present disclosure, the light-emitting element is an organic light-emitting diode or an inorganic light-emitting diode.

For example, in the display panel provided by an example of the present disclosure, the image recognition unit is an iris recognition unit; and the iris recognition unit is formed on the semiconductor base substrate and configured to recognize an iris image acquired by the imaging array.

For example, in the display panel provided by an example of the present disclosure, the iris recognition unit is also configured to: perform image processing on the iris image and obtain a preprocessed image; extract an iris feature in the preprocessed image; and compare the iris feature with an iris image library, and determine whether the iris feature is matched with the iris image library.

For example, the display panel provided by an example of the present disclosure further comprises a read-out circuit, wherein the read-out circuit is formed on the semiconductor base substrate and configured to read out an image signal acquired by the imaging array and transmit the image signal to the image recognition unit.

An embodiment of the present disclosure provides a display device, display device discloses the display panel as mentioned above.

An embodiment of the present disclosure provides a method for manufacturing a display panel, the method for manufacturing a display panel comprises: providing a semiconductor base substrate; forming a display array and an imaging array on the semiconductor base substrate, in which the display array includes a plurality of display pixels arranged in an array, each of the plurality of display pixels includes at least one display subpixel, each of at least one display subpixel includes a light-emitting element, the imaging array includes a plurality of imaging pixels, each of the plurality of imaging pixels includes at least one imaging subpixel, a plurality of display subpixels are in mixed arrangement with a plurality of imaging subpixels; and forming an image recognition unit on the semiconductor base substrate, in which the image recognition unit is configured to recognize an image acquired by the image array.

For example, in the method for manufacturing a display panel provided by an example, the image recognition unit is an iris recognition unit, and the iris recognition unit is formed on the semiconductor base substrate and configured to recognize an iris image acquired by the image array.

For example, in the method for manufacturing a display panel provided by an example, each of the plurality of display pixels includes at least three display subpixels, the light-emitting elements of the at least three display subpixels in the display pixel emit lights with different colors, and each of the plurality of imaging subpixels is disposed between two, three or four adjacent display subpixels of the plurality of display subpixels.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a schematic plan view of a display panel provided by an embodiment of the present disclosure;

FIG. 2 is another schematic structural plan view of a display panel provided by an embodiment of the present disclosure;

FIG. 3 is still another schematic structural plan view of a display panel provided by an embodiment of the present disclosure;

FIG. 4 is a workflow diagram of an iris recognition unit in a display panel provided by an embodiment of the present disclosure;

FIG. 5 is a schematic diagram of function modules in a display panel provided by an embodiment of the present disclosure;

FIG. 6 is a schematic diagram of a display device provided by another embodiment of the present disclosure; and

FIG. 7 is a flow diagram of a method for manufacturing a display panel, provided by still another embodiment of the present disclosure.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

Unless otherwise defined, all the technical and scientific terms used herein have the same meanings as commonly understood by one of ordinary skill in the art to which the present disclosure belongs. The terms, such as “first,” “second,” or the like, which are used in the description and the claims of the present disclosure, are not intended to indicate any sequence, amount or importance, but for distinguishing various components. Further, in embodiments of the present disclosure, the same or similar reference numbers denote the same or similar components.

With the rapid development of mobile payment and mobile information communication, there is an increasing demand for more convenient and effective security technologies for display devices. Human-body biometric recognition technology such as iris recognition technology and face recognition technology has been gradually adopted by mobile electronic devices. If the display device has human-body biometric recognition function such as iris recognition or face recognition by introducing an image recognition module, the volume, weight, cost and power consumption of the display device are increased, which conflicts with the current consumers' requirement and expectancy on electronic products, especially consumer electronic products.

Embodiments of the present disclosure provide a display panel, a display device and a method for manufacturing the display panel, which can improve the safety of the display panel and meanwhile reduce the volume and the weight of the display panel and the display device comprising the display panel by integration of human-body biometric recognition function such as iris recognition and/or face recognition into the display panel.

At least one embodiment of the present disclosure provides a display panel, which comprises a semiconductor base substrate, a display array, an imaging array and an image recognition unit. The display array is formed on the semiconductor base substrate and includes a plurality of display pixels arranged in an array; each display pixel includes at least one display subpixel; and each display subpixel includes a light-emitting element. The imaging array is formed on the semiconductor base substrate and includes a plurality of imaging pixels; each imaging pixel includes at least one imaging subpixel; and the plurality of display subpixels are in mixed arrangement with the plurality of imaging subpixels. Orthographic projections of the display subpixels and the imaging subpixels on the semiconductor base substrate are not overlapped. The image recognition unit is configured to recognize images acquired by the imaging array.

For instance, FIG. 1 is a schematic plan view of a display panel 100 provided by an embodiment of the present disclosure. As illustrated in FIG. 1, the display panel 100 comprises a semiconductor base substrate 110, a display array 120, an imaging array 130 and an image recognition unit 140. For instance, the image recognition unit 140 may be a human-body biological image recognition unit. The display array 120 is formed on the semiconductor base substrate 110 and includes a plurality of display pixels 121 arranged in an array; each display pixel 121 includes three display subpixels 122; each display subpixel 122 includes a light-emitting element 123; and the light-emitting elements 123 of the three adjacent display subpixels 122 in the display pixel 121 have mutually different light-emitting colors (e.g., respectively emit red light, green light and blue light). The imaging array 130 is formed on the semiconductor base substrate 110 and includes a plurality of imaging pixels 131; the plurality of imaging pixels 131, for instance, may also be arranged in an array; and each imaging pixel 131 includes one imaging subpixel 132. The plurality of display subpixels 122 are in mixed arrangement with the plurality of imaging subpixels 132. For instance, each imaging subpixel 132 is disposed between four adjacent display subpixels 122. The image recognition unit 140 is configured to recognize images acquired by the imaging array 130.

The mixed arrangement mode of the display subpixels 122 and the imaging subpixels 132 is not limited to the case as shown in FIG. 1 and may also be the following cases.

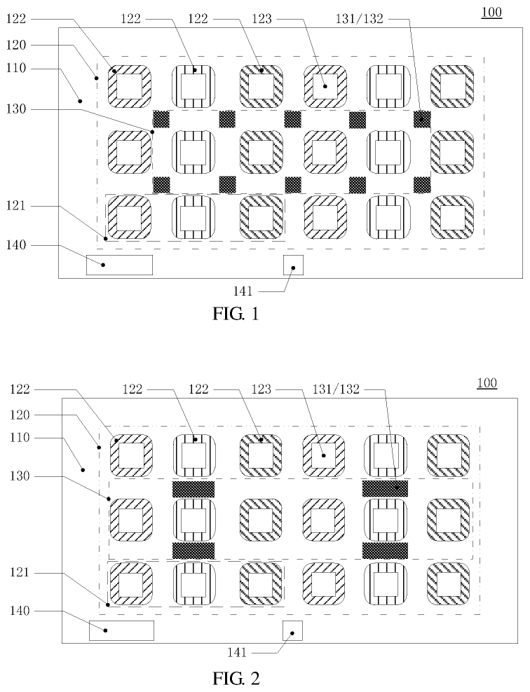

For instance, as shown in FIG. 2, in one example, each display pixel 121 includes three display subpixels 122; light-emitting elements 123 of the three display subpixels 122 in the display pixel 121 have mutually different light-emitting colors; each imaging pixel 131 includes one imaging subpixel 132; each imaging pixel 131 and/or imaging subpixel 132 is disposed between two adjacent display pixels 121 in a column direction; and obviously, each imaging pixel 131 and/or imaging subpixel 132 may also be disposed between two adjacent display pixels 121 in a row direction, or disposed between four adjacent display pixels 121 (formed by four adjacent display pixels in two adjacent rows and two adjacent columns), or disposed between two adjacent display subpixels 122 in the row direction or the column direction.

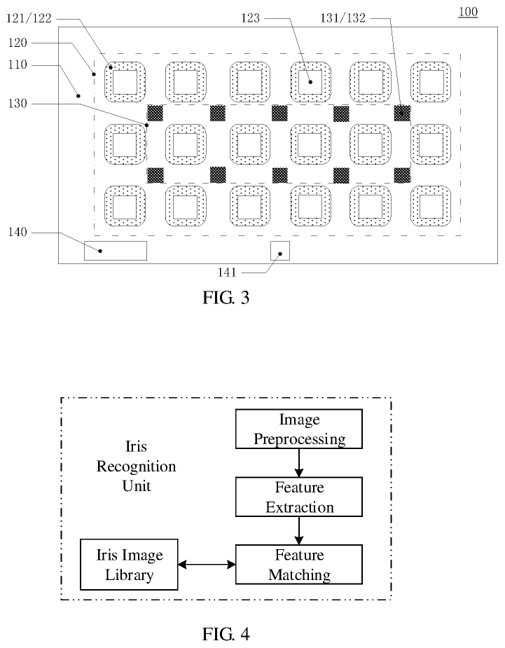

For instance, as shown in FIG. 3, in one example, each display pixel 121 includes one display subpixel 122; each imaging pixel 131 includes one imaging subpixel 132; each imaging pixel 131/imaging subpixel 132 is disposed between four adjacent display subpixels 122 (formed by four adjacent display subpixels in two adjacent rows and two adjacent columns); and obviously, each imaging pixel 131/imaging subpixel 132 may also be disposed between two adjacent display pixels 121 in the row direction or the column direction.

For instance, when the pixel arrangement mode of the display pixel is delta (Δ) pixel arrangement, each imaging pixel 131/imaging subpixel 132 may also be disposed between three adjacent display subpixels 122 or disposed between three adjacent display pixels 121.

For instance, each imaging pixel 131 may further include a plurality of imaging subpixels 132 (for instance, each imaging pixel 131 includes three imaging subpixels 132); the operating wavelengths of the imaging subpixels 132 in the imaging pixel 131 may be different; and the imaging subpixel 132 may be disposed between the display subpixels 122 in mixed arrangement according to actual application demands. No specific limitation will be given here in the embodiment of the present disclosure.

For instance, according to actual application demands, the imaging subpixel 132 may be disposed between two, three or four adjacent display pixels 121 or two, three or four adjacent display subpixels 122 of the entire display array 120, and may also be only disposed between two, three or four adjacent display pixels 121 or two, three or four adjacent display subpixels 122 in a certain area of the display array 120. For instance, the spacing and the density of the imaging subpixels 132 may be correspondingly set according to the size of the display array 120 and the actual application demand.

For instance, according to actual application demands, the size of the imaging subpixel 132 may be less than that of the display subpixel 122. Obviously, the size of the imaging subpixel 132 may also be equal to or greater than the size of the display subpixel 122.

For instance, according to actual application demands, a height of a working surface (an electromagnetic wave receiving surface, e.g., an infrared light receiving surface) of the imaging subpixel 132 may be greater than that of a light-emitting surface of the display subpixel 122. Obviously, the height of the working surface of the imaging subpixel 132 may also be equal to or less than that of the light-emitting surface of the display subpixel 122.

For instance, according to actual application demands, the imaging subpixel 132 may also be disposed between the display subpixels 122 in substitutional mixed arrangement. For instance, one of the plurality of (e.g., four) display subpixels 122 in the row direction may be substituted into the imaging subpixel 132. Moreover, for instance, one of the plurality of (e.g., four) display subpixels 122 in the column direction may also be substituted into the imaging subpixel 132. No limitation will be given here in the embodiment of the present disclosure.

In summary, as for different pixel array arrangement modes and actual application demands, the specific mixed arrangement mode of the display subpixels 122 and the imaging subpixels 132 may be set according to specific conditions and demands. Therefore, no specific limitation will be given to the mixed arrangement mode of the display subpixels 122 and the imaging subpixels 132 in the embodiment of the present disclosure.

Due to adoption of the mixed arrangement mode of the display subpixels 122 and the imaging subpixels 132, the imaging array 130 does not need to occupy additional space of the display panel 100. Therefore, the size of the display panel 100 can be reduced; the integration level of a product can be improved; and the volume of the product can be reduced.

For instance, materials of the semiconductor base substrate 110 may be monocrystalline, germanium, gallium arsenide or the like, for example, monocrystalline. For instance, the imaging array 130 may be formed on the semiconductor base substrate 110 by semiconductor integrated circuit (IC) manufacturing process for manufacturing, for instance, Complementary Metal-Oxide-Semiconductor Transistor (CMOS) IC. For instance, the light-emitting element 123 may be an organic LED (OLED) or an inorganic LED (e.g., a micro-LED). For instance, the OLED type light-emitting element may be formed by the following means: firstly, forming a driving array layer on the semiconductor base substrate 110 by the semiconductor IC manufacturing process, in which the driving array layer includes a driving circuit (for instance, including a switching transistor, a driving transistor, a storage capacitor, etc.) for driving the light-emitting elements to emit light; secondly, forming an electrode layer on the driving array layer including the driving circuit, in which the electrode layer is, for instance, electrically connected with a source electrode or a drain electrode of the driving transistor; and thirdly, evaporating organic functional layers, for instance, an electron injection layer (EIL), an electron transport layer (ETL), an organic emission layer (EML), a hole transport layer (HTL), a hole injection layer (HIL) and a transparent electrode, on the electrode layer. For instance, the inorganic LED (e.g., micro-LED) type light-emitting element may be formed on the semiconductor base substrate 110 by using metal organic chemical vapor deposition (MOCVD) process.

For instance, each imaging subpixel of the imaging array 130 may include a photoelectric detection unit and a read-out circuit which are, for instance, formed on the semiconductor base substrate 110 by the semiconductor IC manufacturing process. The photoelectric detection unit, for instance, includes a photoelectric sensor. The photoelectric sensor may include a photosensitive element (e.g., a photosensitive diode or a photistor). The semiconductor IC manufacturing process, for instance, may refer to the traditional process for manufacturing the imaging array (imaging device) and the display device. No further description will be given here.

For instance, the image recognition unit 140 may be a human-body biological image recognition unit such as an iris recognition unit, a face recognition unit or a fingerprint recognition unit. The image recognition unit 140 may extract features from human-body biological images acquired by the imaging array 130, compare the obtained features with a prestored human-body biological image library, and determine whether they are matched. Due to adoption of the human-body biological feature recognition technology, the use safety of the display panel 100 is improved. For instance, the image recognition unit 140 may be formed on the semiconductor base substrate 110 by the semiconductor IC manufacturing process.

For instance, when the image recognition unit 140 is an iris recognition unit, the iris recognition unit may be formed on the semiconductor base substrate 110 and disposed on the display array 120 side, namely a display side of the display panel 100, and is configured to recognize an iris image acquired by the imaging array 130. For instance, the iris recognition unit may be formed on the semiconductor base substrate 110 and disposed on the upper side or the right side of the display array 120. For instance, the iris recognition unit may recognize the iris image acquired by the imaging array 130 by a method as shown in FIG. 4.

Firstly, the iris image acquired by the imaging array is subjected to image processing to obtain a preprocessed image. An objective of performing the image processing on the iris image and obtaining the preprocessed image is to allow the preprocessed image to be able to satisfy the requirement of iris feature extraction. For instance, the step of the image processing for the iris image may include: (1) iris positioning: determining positions of an inner circle, an outer circle and a quadratic curve in the image, in which the inner circle is a boundary between the iris and a pupil, the outer circle being a boundary between the iris and a sclera, the quadratic curve being a boundary between the iris and the upper and lower eyelids; (2) iris image normalization: adjusting a size of the iris in the image to be a fixed size set by a recognition system; and (3) image enhancement, with an objective of improving the recognition rate of iris information in the image by performing brightness, contrast and smoothness processing on the normalized image. Then, iris features in the preprocessed images may be extracted. For instance, feature points required for iris recognition may be extracted from the preprocessed image by specific algorithm and then encoded. Finally, the extracted iris features are compared with an iris image library, and whether they are matched is determined. For instance, whether there is a matched iris in the iris image library is determined by matching of extracted feature codes and iris image feature codes in the library one by one.

As the iris features of the human beings have been determined in random combination manner before they were born, the iris features are unchanged for life once formed. The accuracy of iris recognition is the highest in various kinds of biological recognition. Therefore, the use safety of the display panel can be further improved by integration of the iris recognition unit into the display panel.

For instance, the photoelectric detection unit (e.g., the photoelectric sensor) in the imaging pixel 131 may work in visible light band and/or near infrared band. For instance, an operating wavelength of the imaging pixel 131 working in the visible light band may be in a range of 400 nm-799 nm, and an operating wavelength of the imaging pixel 131 working in the near infrared band may be in a range of 800 nm-1,200 nm and/or 1,201 nm-2,500 nm. When the imaging pixel 131 operates in the near infrared band, the imaging array 130 may acquire more subtle and clearer iris images, so the recognition rate can be improved. At this point, the display panel 100 further comprises an infrared light source 141 (for instance, the infrared light source 141 is a near infrared light source). The infrared light source 141 may be disposed on a side of the display array 120 and is configured to emit infrared light to an user. For instance, the infrared light source 141 may be disposed on a lower part of the display array 120. For instance, the infrared light source 141 may be disposed at a corresponding position of the semiconductor base substrate 110 by optical adhesive, welding and other manners. For instance, when the imaging pixel 131 operates in the visible light band, partial optical elements in the display array 120 may be taken as a light source for scanning the eyes, so no additional light source is required to be arranged. Thus, the volume, the weight and the cost of the display panel 100 can be further reduced.

As the imaging array, the TFT, the image recognition unit and the like may be directly formed on the semiconductor base substrate by, for instance, semiconductor IC manufacturing process, sizes of the imaging array, the TFT, the image recognition unit and the like can be reduced, and the number of external wirings can be reduced. Thus, the volume and the weight of the display panel and the display device can be reduced. As an organic light-emitting diode may be formed on the semiconductor base substrate by evaporation process or an inorganic LED (e.g., micro-LED) may be formed on the semiconductor base substrate by MOCVD process, the human-body biological recognition function may be integrated into the display panel. Thus, the safety of the display panel can be improved and meanwhile the volume and the weight of the display panel and the display device can be reduced.

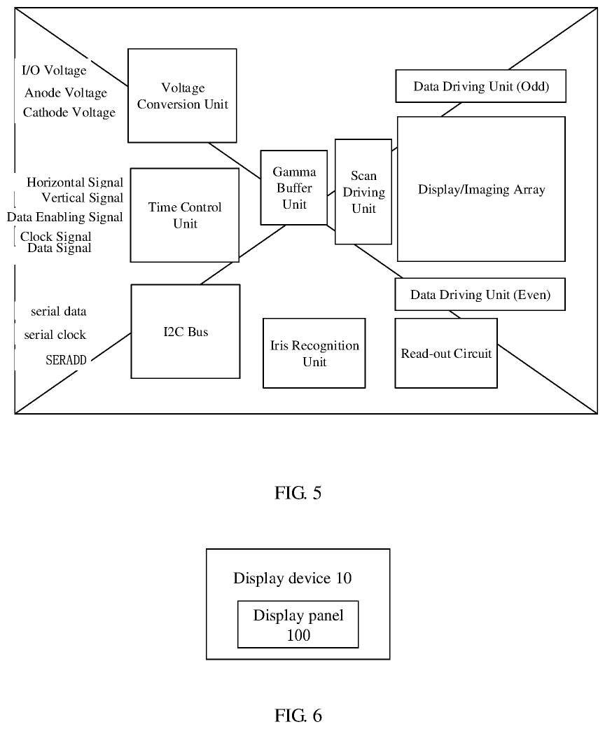

For instance, FIG. 5 is a schematic diagram of function modules of the display panel provided by an embodiment of the present disclosure. As illustrated in FIG. 5, the display panel further comprises a read-out circuit. The read-out circuit may be formed on the semiconductor base substrate and is configured to read out an image signal acquired by the imaging array and transmit the image signal to the image recognition unit. For instance, the read-out circuit may be formed on the semiconductor base substrate by using the semiconductor IC manufacturing process.

For instance, as shown in FIG. 5, the display panel may further comprise a time control unit, data driving units, a scan driving unit and the like. The time control unit is configured to control the light-emitting elements in the display array by controlling the data driving units (e.g., the data driving units (odd) and the data driving units (even) as shown in FIG. 5) and the scan driving unit, so as to realize the display function. The time control unit, for instance, may receive various kinds of control signals (e.g., horizontal signal, vertical signal, data enabling signal and clock signal), so as to respectively control the data driving units and the scan driving unit to operate.

For instance, the display panel may further comprise a gamma buffer unit. The gamma buffer unit is configured to detect a dark part and a light part in the image signal, increase the ratio of the dark part to the light part, and then improve the contrast of the display image.

For instance, the time control unit, the data driving units, the scan driving unit and the gamma buffer unit may be formed on the semiconductor base substrate by using the semiconductor IC manufacturing process.

For instance, the human-body biological image acquired by the read-out circuit may also be transmitted to the time control unit via the image recognition unit and inputted as display data signal thereof, so the human-body biological image acquired by the imaging array can be displayed.

For instance, as shown in FIG. 5, the display panel may further comprise an inter-IC (I2C) bus. The I2C bus is a bidirectional two-wire continuous bus and is configured to provide a communication line between ICs. In the display panel, the I2C bus is configured to realize the communication between the time control unit and the gamma buffer unit. The I2C bus, for instance, may be formed on the semiconductor base substrate by using the semiconductor IC manufacturing process. For instance, as shown in FIG. 5, the display panel may further comprise a voltage conversion unit. The voltage conversion unit is configured to receive external voltage (for instance, I/O voltage or anode voltage and cathode voltage of the light-emitting element) and convert the external voltage into appropriate voltage to drive the display array and the imaging array. As shown in FIG. 5, the I2C bus may receive signals such as serial data, serial clock and SERADD, in which the SERADD refers to an address of the lowest weighted bit of a serial interface.

As one or more of the read-out circuit, the time control unit, the data driving units, the scan driving unit, the gamma buffer unit and the I2C bus may be directly formed on the semiconductor base substrate by the semiconductor IC manufacturing process, the size thereof can be reduced and the number of external wirings can be reduced. Thus, the volume, the weight and the cost of the display panel and the display device can be reduced.

For instance, FIG. 6 is a schematic diagram of a display device 10 provided by another embodiment of the present disclosure. The display device 10 comprises the display panel 100 provided by any embodiment of the present disclosure. It should be noted that other necessary components of the display device 10 shall all be understood by those skilled in the art to be included, are not further described here, and shall not be construed as the limitation of the present disclosure. The display device 10 may integrate the human-body biological recognition function into the display panel 100, so as to improve the safety of the display panel 100 and meanwhile reduce the volume and the weight of the display panel 100 and the display device 10.

For instance, based on the same invention concept, an embodiment of the present disclosure further provides a method for manufacturing a display panel. The method for manufacturing the display panel comprises: providing a semiconductor base substrate; forming a display array and an imaging array on the semiconductor base substrate; and forming an image recognition unit on the semiconductor base substrate. The display array includes a plurality of display pixels arranged in an array; each display pixel includes at least one display subpixel; each display subpixel includes a light-emitting element; the imaging array includes a plurality of imaging pixels; each imaging pixel includes at least one imaging subpixel; a plurality of display subpixels are in mixed arrangement with a plurality of imaging subpixels; and the image recognition unit is configured to recognize images acquired by the imaging array.

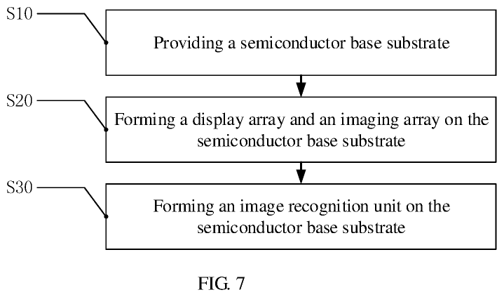

For instance, FIG. 7 is a flow diagram of a method for manufacturing a display panel, provided by still another embodiment of the present disclosure. Taking the display panel as shown in FIG. 1 as an example, as shown in FIG. 7, the manufacturing method may comprise the following steps:

S10: providing a semiconductor base substrate;

S20: forming a display array and an imaging array on the semiconductor base substrate; and

S30: forming an image recognition unit on the semiconductor base substrate.

For instance, as shown in FIG. 1, the forming the display array and the imaging array on the semiconductor base substrate includes: forming a plurality of display pixels arranged in an array on the semiconductor base substrate, in which each display pixel includes three display subpixels; each display subpixel includes a light-emitting element; and light emitted by the light-emitting elements of the three display subpixels in the display pixel have mutually different colors. For instance, the forming the display array and the imaging array on the semiconductor base substrate further includes: forming a plurality of imaging pixels on the semiconductor base substrate, in which each imaging pixel includes one imaging subpixel. A plurality of display subpixels are in mixed arrangement with a plurality of imaging subpixels. For instance, each imaging subpixel is disposed between four adjacent display subpixels. The mixed arrangement mode of the display subpixels and the imaging subpixels is not limited to the above means. Other arrangement modes may refer to an embodiment of the display panel. No limitation will be given here in the embodiment of the present disclosure. Due to adoption of the mixed arrangement mode of the display subpixels and the imaging subpixels, the imaging array does not need to occupy additional space of the display panel, so the size of the display panel can be reduced.

For instance, a material of the semiconductor base substrate may be monocrystalline, germanium, gallium arsenide, etc. For instance, the imaging array may be formed on the semiconductor base substrate by using the semiconductor IC manufacturing process. For instance, the light-emitting element may be an OLED or an inorganic LED (e.g., a micro-LED). For instance, the OLED type light-emitting element may be formed by the following means: firstly, forming a driving array layer on the semiconductor base substrate by using the semiconductor IC manufacturing process, in which the driving array layer includes a driving circuit (for instance, including a switching transistor, a driving transistor, a storage capacitor, etc.) for driving the light-emitting element to emit light; secondly, forming an electrode layer on the driving array layer comprising the driving circuit, in which the electrode layer is, for instance, electrically connected with a source electrode or a drain electrode of the driving transistor; and thirdly, evaporating various organic function layers, for instance, an EIL, an ETL, an organic EML, a HTL, a HIL and a transparent electrode, on the electrode layer. The inorganic LED (e.g., the micro-LED) type light-emitting element may be formed on the semiconductor base substrate by MOCVD.

For instance, the image recognition unit may be formed on the semiconductor base substrate by using the semiconductor IC manufacturing process. For instance, the image recognition unit may be a human-body biological image recognition unit such as an iris recognition unit, a face recognition unit or a fingerprint recognition unit. The image recognition unit may extract features from the human-body biological image acquired by the imaging array, compare the obtained features with a prestored human-body biological image library, and determine whether they are matched. Due to adoption of human-body biological feature recognition technology, the use safety of the display panel is improved. The specific working principle of the image recognition unit refers to the embodiment of the display panel. No further description will be given here.

For instance, the imaging pixel may work in visible light band and/or near infrared band. For instance, an operating wavelength of the imaging pixel working in the visible light band may be in a range of 400 nm-799 nm, and an operating wavelength of the imaging pixel working in the near infrared band may be in a range of 800 nm-1,200 nm and/or 1,201 nm-2,500 nm. When the imaging pixel operates in the near infrared band, the imaging array may acquire more subtle and clearer iris images, so the recognition rate can be improved. At this point, the display panel further comprises an infrared light source (for instance, the infrared light source is a near infrared light source). The infrared light source may be disposed on a side of the display array and is configured to emit infrared light to an user. For instance, the infrared light source may be disposed on a lower part of the display array. For instance, the infrared light source may be disposed at a corresponding position of the semiconductor base substrate by optical adhesive, welding and other manners. For instance, when the imaging pixel operates in the visible light band, partial optical elements in the display array may be taken as a light source for scanning the eyes, so no additional light source is required to be arranged. Thus, the volume, the weight and the cost of the display panel can be further reduced.

As the imaging array, the TFT, the image recognition unit and the like may be directly formed on the semiconductor base substrate by using, for instance, the semiconductor IC manufacturing process, the size of the imaging array, the TFT, the image recognition unit and the like can be reduced, and the number of external wirings can be reduced. Thus, the volume and the weight of the display panel and the display device can be reduced. As an OLED may be formed on the semiconductor base substrate by evaporation process or an inorganic LED (e.g., micro-LED) may be formed on the semiconductor base substrate by MOCVD process, the human-body biological recognition function may be integrated into the display panel. Thus, the safety of the display panel can be improved and meanwhile the volume and the weight of the display panel and the display device can be reduced.

For instance, the manufacturing method further comprises: forming one or more of a read-out circuit, a time control unit, a data driving unit, a scan driving unit, a gamma buffer unit and an I2C bus by, for instance, semiconductor IC manufacturing process. For instance, the read-out circuit is configured to read out an image signal acquired by the imaging array and transmit the image signal to the image recognition unit. For instance, the time control unit is configured to control the light-emitting element in the display array by controlling the data driving unit and the scan driving unit, so as to realize the display function. For instance, the gamma buffer unit is configured to detect a dark part and a light part in the image signal, increase the ratio of the dark part to the light part, and then improve the contrast of the display image. For instance, the human-body biological image acquired by the read-out circuit may also be transmitted to the time control unit via the image recognition unit and inputted as display data thereof, so the human-body biological image acquired by the imaging array can be displayed. For instance, the I2C bus is configured to realize the communication between the time control unit and the gamma buffer unit.

As one or more of the read-out circuit, the time control unit, the data driving unit, the scan driving unit, the gamma buffer unit and the I2C bus may be directly formed on the semiconductor base substrate by the semiconductor IC manufacturing process, the size thereof can be reduced and the number of external wirings can be reduced. Thus, the volume, the weight and the cost of the display panel and the display device can be reduced.

Embodiments of the present disclosure provide a display panel, a display device and a method for manufacturing a display panel, which can improve the safety of the display panel and meanwhile reduce the volume and the weight of the display panel and the display device comprising the display panel by integration of the human-body biological recognition function such as iris recognition and/or face recognition into the display panel.

The embodiments of the TFT and the manufacturing method thereof, the array substrate and the manufacturing method thereof, and the display device may refer to each other. In addition, the embodiments of the present disclosure and the characteristics in the embodiments may be mutually combined without conflict.

The application claims priority to the Chinese patent application No. 201610995314.9, filed Nov. 11, 2016, the disclosure of which is incorporated herein by reference as part of the application.

1. A display panel, comprising:
a semiconductor base substrate;
a display array, formed on the semiconductor base substrate and including a plurality of display pixels arranged in an array, wherein, each of the plurality of display pixels include at least one display subpixel, and each display subpixel includes a light-emitting element;
an imaging array, formed on the semiconductor base substrate and including a plurality of imaging pixels, wherein, each of the plurality of imaging pixels includes at least one imaging subpixel, and a plurality of display subpixels and a plurality of imaging subpixels are arranged in a mixed arrangement; and
an image recognition unit, configured to recognize an image acquired by the imaging array.

2. The display panel according to claim 1, wherein each of the plurality of imaging subpixels includes a photoelectric detection unit, and the photoelectric detection unit includes a photoelectric sensor.

3. The display panel according to claim 1, wherein each of the plurality of imaging pixels is disposed between two, three or four adjacent display pixels of the plurality of display pixels.

4. The display panel according to claim 1, wherein each of the plurality of display pixels includes at least three display subpixels, the light-emitting elements of the at least three display subpixels in the display pixel emit lights with different colors, and each of the plurality of imaging subpixels is disposed between two, three or four adjacent display subpixels of the plurality of display subpixels.

5. The display panel according to claim 1, wherein an operating band of the imaging pixel is one or a combination of 400 nm-799 nm, 800 nm-1,200 nm and 1,201 nm-2,500 nm.

6. The display panel according to claim 1, wherein material of the semiconductor base substrate include monocrystalline, germanium or gallium arsenide.

7. The display panel according to claim 1, further comprising an infrared light source, wherein the infrared light source is disposed on the semiconductor base substrate and configured to emit infrared light to a user.

8. The display panel according to claim 1, wherein the light-emitting element is an organic light-emitting diode or an inorganic light-emitting diode.

9. The display panel according to claim 1, wherein the image recognition unit is an iris recognition unit; and
the iris recognition unit is formed on the semiconductor base substrate and configured to recognize an iris image acquired by the imaging array.

10. The display panel according to claim 9, wherein the iris recognition unit is also configured to:
perform image processing on the iris image and obtain a preprocessed image;
extract an iris feature in the preprocessed image; and
compare the iris feature with an iris image library, and determine whether the iris feature is matched with the iris image library.

11. The display panel according to claim 1, further comprising a read-out circuit, wherein the read-out circuit is formed on the semiconductor base substrate and configured to read out an image signal acquired by the imaging array and transmit the image signal to the image recognition unit.

12. A display device, comprising the display panel according to claim 1.

13. A manufacturing method of the display panel according to claim 1, comprising:
providing a semiconductor base substrate;
forming a display array and an imaging array on the semiconductor base substrate, in which the display array includes a plurality of display pixels arranged in an array, each of the plurality of display pixels includes at least one display subpixel, each of at least one display subpixel includes a light-emitting element, the imaging array includes a plurality of imaging pixels, each of the plurality of imaging pixels includes at least one imaging subpixel, a plurality of display subpixels are in mixed arrangement with a plurality of imaging subpixels; and
forming an image recognition unit on the semiconductor base substrate, in which the image recognition unit is configured to recognize an image acquired by the image array.

14. The manufacturing method according to claim 13, wherein the image recognition unit is an iris recognition unit, and the iris recognition unit is formed on the semiconductor base substrate and configured to recognize an iris image acquired by the image array.

15. The manufacturing method according to claim 13, wherein each of the plurality of display pixels includes at least three display subpixels, the light-emitting elements of the at least three display subpixels in the display pixel emit lights with different colors, and each of the plurality of imaging subpixels is disposed between two, three or four adjacent display subpixels of the plurality of display subpixels.

16. The display panel according to claim 2, wherein the image recognition unit is an iris recognition unit; and
the iris recognition unit is formed on the semiconductor base substrate and configured to recognize an iris image acquired by the imaging array.

17. The display panel according to claim 3, wherein the image recognition unit is an iris recognition unit; and
the iris recognition unit is formed on the semiconductor base substrate and configured to recognize an iris image acquired by the imaging array.

18. The display panel according to claim 4, wherein the image recognition unit is an iris recognition unit; and
the iris recognition unit is formed on the semiconductor base substrate and configured to recognize an iris image acquired by the imaging array.

19. The display panel according to claim 5, wherein the image recognition unit is an iris recognition unit; and
the iris recognition unit is formed on the semiconductor base substrate and configured to recognize an iris image acquired by the imaging array.

20. The display panel according to claim 6, wherein the image recognition unit is an iris recognition unit; and
the iris recognition unit is formed on the semiconductor base substrate and configured to recognize an iris image acquired by the imaging array.
